(19) United States
(12) Patent Application Publication
(10) Pub. No.: US 2012/0079346 A1
(43) Pub. Date: Mar. 29, 2012

(54) SIMULATED ERROR CAUSING APPARATUS

(75) Inventor: Takatoshi FUKUDA, Kawasaki (JP)

(73) Assignee: Fujitsu Limited, Kawasaki (JP)

(21) Appl. No.: 13/221,365

(22) Filed: Aug. 30, 2011

(30) Foreign Application Priority Data
Sep. 27, 2010 (JP) 2010-216116

(51) Int. Cl. H03M 13/09

(52) U.S. Cl. 714/758; 714/E11.044

(57) ABSTRACT

An information bit and a redundant bit at addresses of memory determined by a random number are both read without receiving error detection or error correction, the bit at a bit position determined by a random number is inverted, and the bit-inverted data is written to the same address of the same memory. The number of bits (one bit, two or more bits, etc.) to be inverted is set appropriately on the basis of what types of errors are to be caused in a simulated manner.

### CROSS-REFERENCE TO RELATED APPLICATIONS

This application is based upon and claims the benefit of priority of the prior Japanese Patent Application No. 2010-216116, filed on Sep. 27, 2010, the entire contents of which are incorporated herein by reference.

### FIELD

The embodiments discussed herein are related to a simulated error causing apparatus that causes, in a simulated manner, a soft error, which occurs in a memory of a semiconductor device.

### BACKGROUND

In recent years, as configurations of semiconductor devices have become more and more detailed, configurations of semiconductor memory circuits have also become very detailed. This has led to a situation where operations of semiconductor memory circuits are prone to be affected by even a very small amount of external energy, bringing about a problem of soft errors caused by alpha rays or cosmic rays (neutron rays) in semiconductor memory. It has become common for large-capacity memory devices to use an ECC circuit to perform single-bit error correction in order to correct errors in data caused by a soft error such as that described above. Further, as semiconductor processes are becoming more and more detailed, problems such as occurrences of soft errors in cache memory in a microprocessor and multi-bit errors caused by neutron rays have also emerged.

Accordingly, countermeasures against soft errors have to be taken, and whether or not such countermeasures work effectively against soft errors has to be checked. In order to perform this check, it is necessary to cause a soft error and to check the operations in a simulated manner.

Among conventional techniques, there is a method in which a simulated error is implanted in memory. However, this method requires the memory units to be connected via a socket or a connector. Also, this method cannot be applied to cache memory included in the same package as the CPU.
Patent Document 1: Japanese Laid-open Patent Publication No. 2004-21922

### SUMMARY

A simulated error causing apparatus according to an aspect of the present embodiment includes an information storage unit to store data including an information bit and a redundant bit, a reading unit to read, from an arbitrarily set address in the information storage unit, data including the information bit and the redundant bit without performing error detection or error correction, and a writing back unit to invert at least one bit at an arbitrarily set bit position in the read data including the information bit and the redundant bit, and to write back the bit-inverted data to an original address in the information storage unit.

According to the following embodiments, a simulated error causing apparatus that causes a simulated error equivalent to a soft error in semiconductor memory is provided.

The object and advantages of the invention will be realized and attained by means of the elements and combinations particularly pointed out in the claims.

It is to be understood that both the foregoing general description and the following detailed description are exemplary and explanatory and are not restrictive of the invention as claimed.

### BRIEF DESCRIPTION OF DRAWINGS

FIG. 1 illustrates a system configuration that uses a simulated error causing apparatus according to the present embodiment;

FIG. 2 illustrates a configuration of a simulated error causing unit;

FIG. 3 explains how to write erroneous information to cache memory (first part);

FIG. 4 explains how to write erroneous information to cache memory (second part);

FIG. 5 illustrates a configuration of the base n counter illustrated in FIG. 2;

FIG. 6A illustrates a configuration of the random number generator having the maximum and minimum numbers, illustrated in FIG. 2;

FIG. 6B also illustrates a configuration of the random number generator having the maximum and minimum numbers, illustrated in FIG. 2;

FIG. 7 illustrates, in detail, a multi-bit error generation ratio control unit illustrated in FIG. 2;

FIG. 8 illustrates a configuration of a simulated error causing unit to cause a triple-bit error as a simulated multi-bit error;

FIG. 9 illustrates, in detail, the multi-bit error generation ratio control unit illustrated in FIG. 8;

FIG. 10 illustrates a configuration of a first example of a multi-core information processing apparatus to which the present embodiment is applied;

FIG. 11 illustrates a configuration of a second example of a multi-core information processing apparatus to which the present embodiment is applied; and

FIG. 12 illustrates, in detail, a simulated error causing unit 93 illustrated in FIG. 11.

### DESCRIPTION OF EMBODIMENTS

A soft error is caused by alpha rays, cosmic rays (neutron rays), power-supply noise or the like, and has a characteristic wherein it works as an error against reading information, but allows normal reading of the information after that information is written. In the following embodiments, a configuration of causing a soft error in an information storage (memory) unit in a simulated manner is described. By causing a soft error in a simulated manner, it is made possible to determine the scope over which the soft error has an effect in an apparatus, and to provide means for confirming that a countermeasure against errors is effective.

In other words, in the following embodiments, an error is caused in a simulated manner in memory in order to confirm whether or not operations are being performed normally and to predict the probability of an error occurring in actual operation conditions in an information processing apparatus that needs a countermeasure against soft errors caused by alpha rays, cosmic rays (neutron rays) or the like.

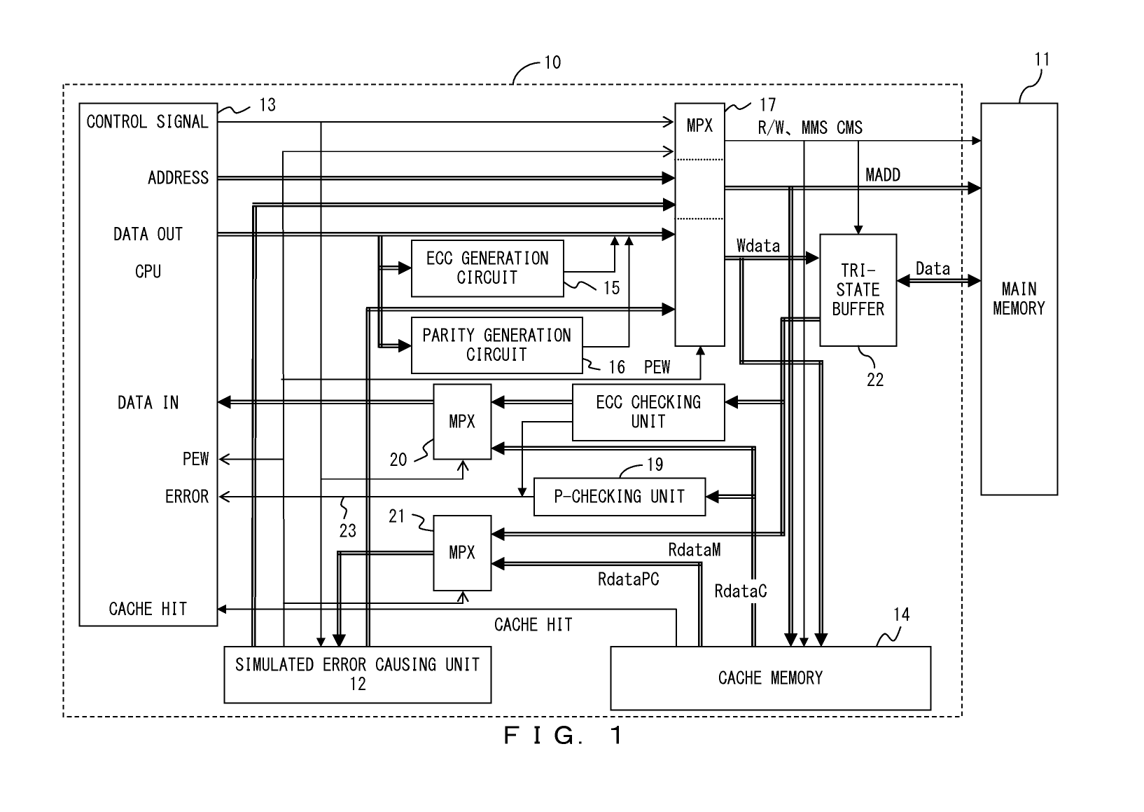

FIG. 1 illustrates a system configuration that uses a simulated error causing apparatus according to the present embodiment.

The part enclosed by the dashed lines in FIG. 1 is usually configured by a semiconductor chip 10, and main memory 11 is connected to the semiconductor chip 10. A simulated error causing unit 12 causes simulated errors periodically during periods of time in which a CPU 13 is not accessing cache memory 14 or the main memory 11. In other words, the simulated error causing unit 12 reads information including redundant bits from the main memory 11 and the cache memory 14 without performing error correction or error detection. Thereafter, the simulated error causing unit 12 inverts one bit or two or more bits selected randomly in the read data, and writes the data back to the original address. When this is performed, the results of inverting bits in the read data including redundant bits are written without writing data output from an ECC generation circuit 15 or a parity generation circuit 16.

This causes an error in one bit or two or more bits when the CPU performs normal reading from the address to which the simulated error causing unit 12 has written the information.

Normal access to memory by the CPU 13 is performed by using an access MMS (Main-Memory-select) signal on the main memory 11, an access CMS (Cache-Memory-Select) signal on the cache memory 14, and an R/W (Reading/Writing) signal of control signals.

In the writing of information to the main memory 11 by the CPU 13, a simulated error writing signal (PEW) “0” is input from the simulated error causing unit so that a multiplexer MPX17 transfers a signal on the CPU 13 side to the main memory 11. The CPU issues an address signal MADD at the same time as asserting an MMS (Main-Memory-Select) signal, and sets the R/W signal to WRITE so that what is written in Data-Out is put into effect. When this is performed, in an ECC generation circuit 15, a check bit is generated from the Data-Out signal transferred from the CPU 13, and this is also written to the main memory 11. Writing data Wdata from the multiplexer MPX17 is transferred to a tri-state buffer 22, and becomes data to be input to the main memory 11. The tri-state buffer 22 has three states, i.e., a state in which the writing data is “1”, a state in which the writing data is “0”, and a state in which data read from the main memory 11 is passed on.

Reading of information from the main memory 11 to the CPU is performed by issuing the address signal MADD at the same time as an MMS signal is asserted, and by setting an R/W signal to READ so that data is read from a desired address through the tri-state buffer 22. When this is performed, read data RdataM includes ECC bits, and an ECC checking unit 18 checks the data. When there are no errors, data bits are transferred to the CPU 13, and the reading process is completed. If a correctable error (a single-bit error when the method is an SEC/DED (Single Error Correct/Double Error Detect) method), the part involving the error in data bits is corrected by the ECC checking unit 18, and the resultant data is transferred to the CPU 13 through a multiplexer MPX20. Also, at the same time as this, the fact that a correctable error has occurred is reported to the CPU 13 using an error signal. When an uncorrectable error (double-bit error in the SEC/DED method) has been detected, the fact that an uncorrectable error has occurred is reported to the CPU 13 using an error signal.

The CPU 13 issues an interrupt when an error is reported, executes an error processing routine, records error logs, resets the entire apparatus, and turns off the power automatically.

In the writing of information from the CPU 13 to the cache memory 14, the simulated error causing unit first sets a simulated error writing signal (PEW) to “0” so that the multiplexer MPX17 transfers a signal on the CPU 13 to the cache memory 14. The CPU 13 asserts a CMS signal, and at the same time issues address signal MADD, thereby setting the R/W signal to WRITE so that what is written in Data-Out is in effect. When this is conducted, in the parity generation circuit 16, a check bit is generated in a data Out signal, and this bit is written to the cache memory 14 together with writing data Wdata.

In the reading of information from the cache memory 14 to the CPU 13, an address signal MADD is issued at the same time as a CMS signal is asserted, and an R/W signal is set to READ, and thereby data is read from a desired address. When there is data specified by a corresponding address signal MADD in the cache memory 14, this fact is regarded as a cache hit, and this fact is reported to the CPU 13. Data RdataC read from the cache memory 14 is transferred to the CPU 13 through the multiplexer MPX20. When this is performed, the parity bit is also read simultaneously, and a P-checking unit 19 performs a parity check. When an error is detected, the parity bit is transferred to the CPU 13 through an error signal line 23.

The CPU 13 issues an interrupt when an error is reported, executes an error processing routine, records error logs, resets the entire apparatus, and turns off the power automatically.

When reading of information from the cache memory 14 is performed and there is no information to be read from the cache memory 14, it is regarded as a cache miss hit, and updating of cache data or the like is performed. In normal operations of a system, the CPU accesses the cache first, and only when it is regarded as a cache miss hit does the CPU access the main memory.

An OR operation is performed on MMS signals and CMS signals (not illustrated), and the results are transferred as CPU-Acc to the simulated error causing unit 12. Further, these results are transferred to the cache memory 14 or the main memory 11, and are used for holding access from the simulated error causing unit 12 to arbitrary memory while the CPU 13 is accessing arbitrary memory. Data RdataM read from the main memory 11 and data RdataPC read from the cache memory 14 are input to a multiplexer MPX21, and one of them is selected to be input to the simulated error causing unit 12. Data RdataM is data read from the main memory, and is to be transferred to the simulated error causing unit 12, and data RdataPC is data read from the cache memory, and is to be transferred to the simulated error causing unit 12. Which of those signals are to be selected is specified by the PMMS (simulated main memory select) signal output from the simulated error causing unit 12 or by a PCMS (simulated cache memory select) signal. A PMMS (simulated main memory select) signal or PCMS (simulated cache memory select) signal specifies whether the simulated error is to be written to the main memory 11 or the cache memory 14. Also, while the simulated error causing unit 12 is accessing one of those types of memory, the PEW signal is set to “1” to be transmitted from the simulated error causing unit 12 to the CPU 13 in order to make access from the CPU 13 wait.

The simulated error causing unit 12 performs an operation of writing information to one of those memory devices at constant intervals (read modify write). Read modify write is a process of reading data, modifying the data, and writing the modified data back to the original address. Control signals for this process, i.e., a PMMS (simulated main memory select) signal, a PCMS (simulated cache memory select) signal, a PR/W (simulated Read/Write) signal, a PADD (simulated address) signal, and a PDATA-Out (simulated data Out) signal are issued. Control signal PEW of the multiplexer MPX17 is set to “1” so that these signals are transferred to one of the memory devices through the multiplexer MPX17. Also, this PEW signal is transferred to the CPU 13, and limits accesses to memory from the CPU 13 until the writing process by the simulated error causing unit 12 is terminated.

Operations of the simulated error causing unit 12 start from reading information from a memory device specified by a PMMS (simulated main memory select) signal or a PCMS (simulated cache memory select) signal. The simulated error causing unit 12 reads information written at the address specified by the address signal (PADD), and transfers it to the simulated error causing unit 12. In the case of this example, information including a check bit (a redundant bit) of ECC to be obtained by accessing the main memory is read to the simulated error causing unit 12 not through the ECC checking unit 18. In the SEC/DED method, data of one or two bits in read data is inverted, and the resultant data is written back to the same address as whole data.

By the CPU 13 reading information from this address, a double-bit error or a single-bit error occurs.

When the simulated error causing unit 12 accesses the cache in this example, RdataPC including data in the tag portion and a parity bit is read to the error generation unit, and one bit in the read data is inverted, and the resultant data is written back to the original address in the cache memory.

A parity error occurs when the CPU 13 reads information from this address.

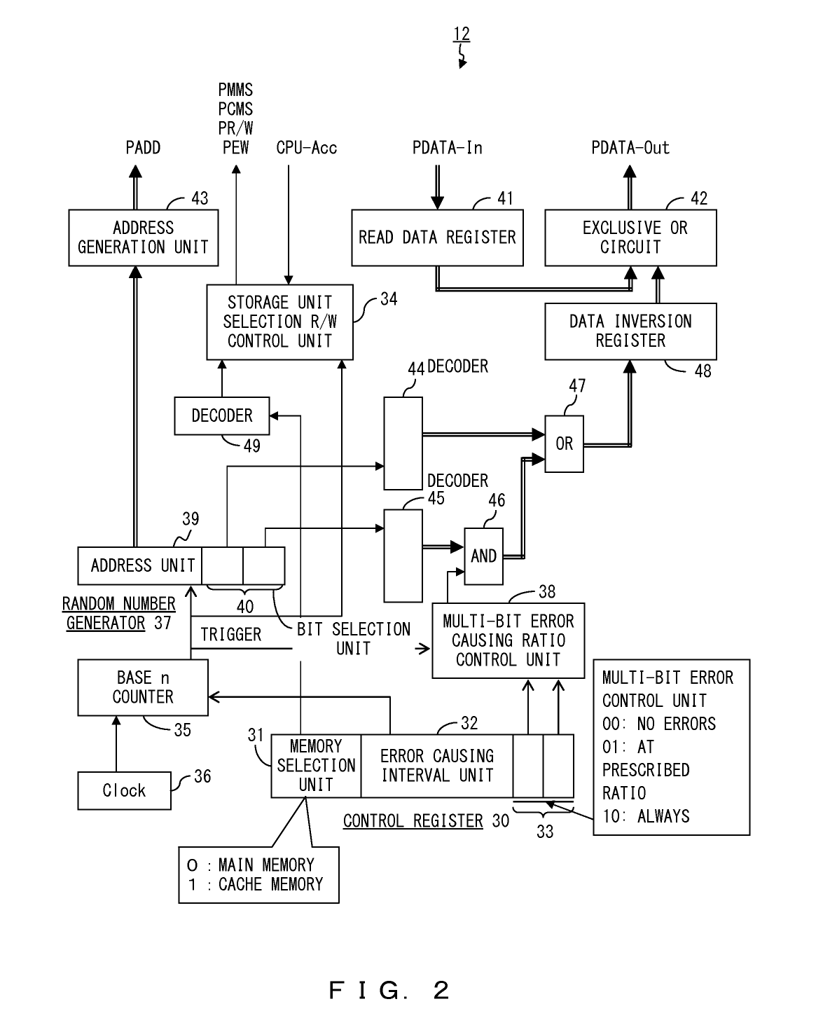

FIG. 2 illustrates a configuration of a simulated error causing unit.

A control register 30 includes a memory selection unit 31, an error causing interval unit 32, and a multi-bit error control unit 33.

The memory selection unit 31 uses a bit value to specify whether the main memory or the cache memory is to be selected. In the example of FIG. 2, two types of memory, i.e., main memory and cache memory, are used as the targets. However, the essence of this example can be applied to a case where cache memory consists of L1 cache and L2 cache or to a case where there are two or more main memory devices even though the number of bits increases. This signal is decoded by a decoder 49, and it is sent to a storage unit selection R/W control unit 34. The storage unit selection R/W control unit 34 confirms that the CPU-Acc signal is in a non-active state, which means that the CPU is not accessing the main memory or the cache memory, decodes a bit in the memory selection unit 31 by using the decoder 49, and issues main memory selection signal PMMS or cache memory selection signal PCMS, and reading/writing signal PR/W. Also, the storage unit selection R/W control unit 34 asserts, to the CPU 13, a PEW signal indicating that the simulated error causing unit 12 is accessing the cache memory or the main memory. This PEW signal serves also as a control signal of the multiplexer MPX17.

The value held by the error causing interval unit 32 determines time intervals at which data is to be inverted. Note that even when data has been inverted, the CPU does not recognize the occurrence of an error unless the CPU reads information from the corresponding address.

In other words, whether or not information is read from an address having inverted data is influenced greatly by system configurations or applications, which applies to environments in practical use. Values to be set will be explained later.

A base n counter 35 increases the count value in accordance with input from a clock 36, and when the value stored in the error causing interval unit 32 and the count value match, the base n counter 35 issues a trigger signal so as to invert memory data, and clears the value of the counter. The trigger signal activates a random number generator 37, and updates a random number value generated by the random number generator 37. Also, the trigger signal is also transferred to the storage unit selection R/W control unit 34, and makes the storage unit selection R/W control unit 34 output a PMMS signal, a PCMS signal, a PR/W signal, and a PEW signal.

The multi-bit error control unit 33 is set in accordance with an error correction detection function of a target memory system. When only an error in one or two bits is caused, the multi-bit error control unit 33 is set to two bits, and instructs on how to cause a multi-bit error. For example, if the value is “00”, no multi-bit errors are caused, when the value is “01”, a multi-bit error is caused at a ratio between a single-bit error and a multi-bit error (double-bit error in FIG. 2) determined by the multi-bit error control unit 33, and when the value is “10”, multi-bit errors are always caused. A particular ratio at which a multi-bit error is caused is set in advance as a prescribed value.

The ratio between single-bit errors and multi-bit errors is determined by a multi-bit error causing ratio control unit 38. Specifically, when a required ratio is n:1 (a multi-bit error is to be caused once while a single-bit error is caused n times), the multi-bit error causing ratio control unit 38 sets the counter to a base n counter, which will be described later. The multi-bit error causing ratio control unit 38 writes inverted multi-bit data to the same address so that a multi-bit error is caused in a simulated manner only when carrying occurs in the counter value, and writes inverted single-bit data so that a single-bit error is caused in a simulated manner when the counter value is increased without the occurrence of carrying. In the example illustrated in FIG. 2, the multi-bit error is a double-bit error.

The address unit 39 of the random number generator 37 corresponds to the capacity of target memory and the address position at which target data is located, and their minimum and maximum values can be set (this will be described later). Outputs from the address unit 39 are processed by an address generation unit 43, and thereafter are transferred, via the MPX 17 (see FIG. 1) and as an address PADD at which data is to be inverted, to the memory selected by a memory selection unit 31 so that a desired address in the memory is accessed.

A bit selection unit 40 includes a bit position selection unit to select one or more bit positions in order to specify which bits in one word line are to be inverted. Specifically, the position of the first bit specifies the position at which a single-bit simulated error is to be caused. When a plurality of bit selection units are provided, it is possible to simulate errors at as many bits as the number of bits that those bit selection units have. Respective bit position generation units of the bit selection units operate independently from the others, generate random numbers independently, and specify positions at which simulated errors are to be caused. Also, the bit selection unit 40 is capable of setting the maximum and minimum values in accordance with the bit width of target memory.

Data is read from memory (the main memory or the cache memory in FIG. 2) in accordance with the address signal, the selection signal that selects one of the cache memory and the main memory, and the R/W signal, and the read data is accumulated in a read data register 41 as PDATA-In via the multiplexer MPX20 or the MPX21 (see FIG. 1), and serves as input to an exclusive OR circuit 42. When this reading is performed, the redundant portion of the memory (the ECC unit and parity bits) is also read to the read data register 41 directly. Also, when the memory is the cache memory, the tag memory portion of the cache memory is also read to the read data register 41.

Other inputs to the exclusive OR circuit 42 are data including a bit string that has been obtained by decoding, using a decoder 44, output from the bit selection unit 40 of the random number generator 37 and that includes only one bit that is “1” in one word. When a multi-bit error is able to be caused, two or more bits (two bits in FIG. 2) in one word may be “1”. By performing an EXCLUSIVE OR operation between the data read from the memory and this data, one bit or two or more bits (two bits in FIG. 2) in the data read from the memory are inverted. This data is written back to the main memory or the cache memory. In the case of a double-bit error in FIG. 2, the bit selection signal in the second bit of the bit selection unit 40 is decoded by a decoder 45, and a bit string in which only the bit at the position that has to be inverted in the bit string is “1” is generated. When a multi-bit error is to be generated, the result of an AND operation on the output of the decoder 45 is obtained through an AND sequence 46 from the multi-bit error causing ratio control unit 38. However, the other input of the AND sequence 46, i.e., the output from the multi-bit error causing ratio control unit 38 is “1”, and a bit in the output from the AND sequence 46 is “1”. When a multi-bit error is not to be generated, the output from the multi-bit error causing ratio control unit 38 is “0”, and outputs from the AND sequence 46 are all “0”. The AND sequence 46 performs an AND operation between the output from the multi-bit error causing ratio control unit 38 and the output from the decoder 45, and when a multi-bit error is to be caused, a bit string in which the position of the second bit is “1” is output. When a multi-bit error is not to be caused, a bit string in which all bits are “0” is output. An OR circuit 47 performs an OR operation between the bit string representing the position of the first bit from the decoder 44 and the bit string representing the position of the second bit from the decoder 45, and inputs the result to a data inversion register 48.

The exclusive OR circuit 42 performs an EXCLUSIVE OR operation between data of the read data register 41, which was read from the memory, and data of the data inversion register 48, which is a bit string in which “1” is set only in the bits to be inverted, and thereby data in which bits of data read from the memory are inverted is output as PDATA-Out.

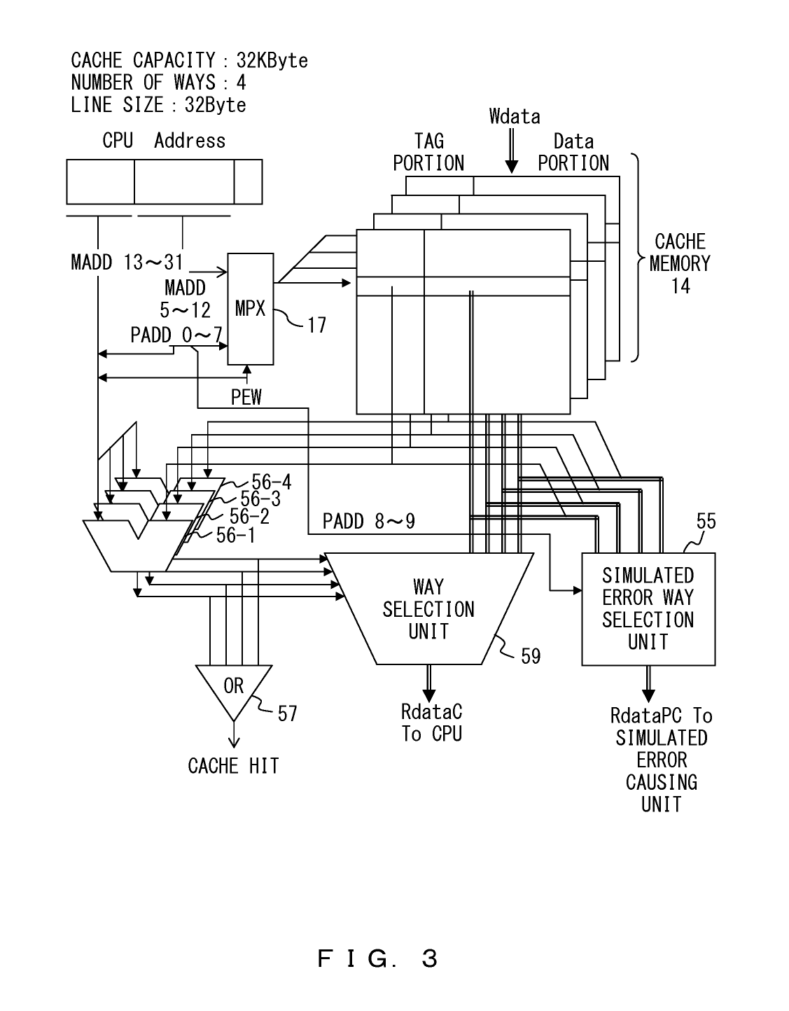

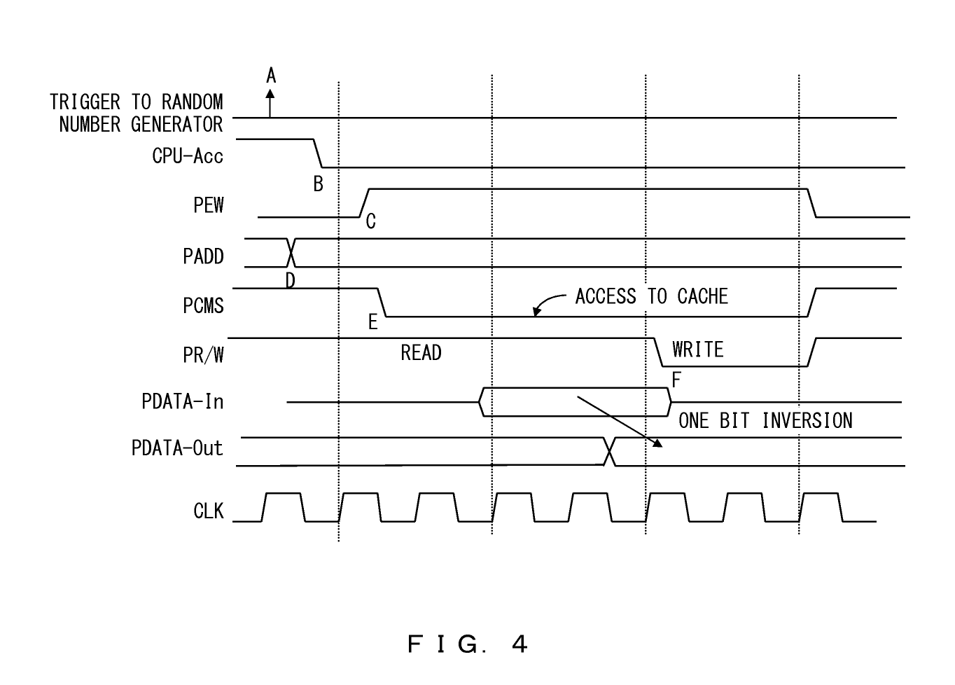

FIGS. 3 and 4 explain how to write erroneous information to the cache memory.

FIG. 3 illustrates an example of a 4-WAY set associative configuration. First, the normal reading of information from the CPU (cache hit) will be explained. Assuming, as an example of a cache configuration, that the capacity is 32K bytes, that 1 Line has 32 bytes, and that the CPU addresses are 0 through 31, upper addresses (MADD13-31) are input to the sides of comparators 56-1 through 56-4, respectively. Cache-Line-Selection addresses (MADD 12 through 5) access the tag portions and the Data portions of the memory via MPX17, and read data of the tag portion is input to the other sides of the comparators 56-1 through 56-4. When the input data matches as a comparison result, it is handled as a cache hit, and the data of hitting WAY is transferred to the CPU selected by a WAY selection unit 59.

Next, explanations will be given for operations of inverting data of the cache memory performed by the simulated error causing unit 12 according to the present invention. A request to write error data to the cache memory 14 is issued in the simulated error causing unit 12. In other words, when a trigger is turned on, it is confirmed that the CPU is not accessing the memory (that CPU-Access is low), and an access request signal PEW to memory is asserted.

Address signals PADD (lower eight bits) of the simulated error causing unit 12 are transferred to the respective WAYs of the cache memory 14 via the multiplexer MPX17, and are read. At the same time, the tag portions are also read. The higher bits of PADD (two in this example) are used for the selection signal of a simulated error WAY selection unit 55 for selecting data of one WAY from data read from the respective WAYs so that the selected data is transferred to the simulated error causing unit 12. The simulated error causing unit 12 inverts one or two bits of the data, and the data is written back to the same address and the same WAY.

Also, in FIG. 3, information in the tag portions is read together with data portion information, and the information of the selected WAY is transferred to the simulated error causing unit 12 via the simulated error WAY selection unit 55. Usually, a tag portion and a data portion are configured using memory cells according to the same technology, making it possible to simultaneously read information from them. By enabling simultaneous reading, circuits can be simpler, and a time period used for testing can be reduced.

When the data of the address read by the CPU is an address of memory only for parity check, it means that a parity error, an ECC correctable error (a single-bit error), or an uncorrectable error (a double-bit error) will occur. Explanations have been given for a single or a double-bit error. However, the method may naturally be expanded to rewriting “n+1” bits in order to respond to an error correction function for multi(n) bit errors.

FIG. 4 is a signal diagram explaining operations according to the present embodiment.

First, a trigger to the random number generator is issued at timing A. The operation starts after waiting for timing B, at which access by the CPU to the cache memory is terminated. The value of the address at which a simulated error is caused is output at timing D. However, because the CPU is accessing the cache memory, the output of the value waits until timing B, at which the access is terminated. When the access by the CPU to the cache memory is terminated at timing B, a PEW signal, prohibiting access by the CPU to the cache memory, is issued at timing C. Immediately after this timing C, the simulated error generation unit accesses the cache memory at timing E, and signal PCMS is set to LOW. First, the simulated error generation unit reads data from the cache memory, and thus signal PR/W is in a READ state. At this moment, data PDATA-In that has been read by the simulated error causing unit is input, and the bits are inverted so that signal PDATA-Out is output. Thereafter, because the simulated error causing unit starts operations of writing information to the cache memory, signal PR/W is tuned to WRITE state at timing F so that signal PDATA-Out is written to the cache memory.

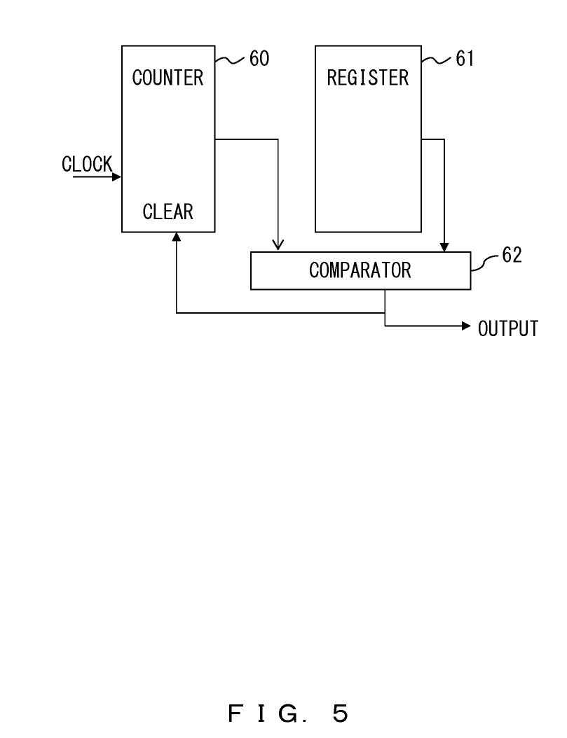

FIG. 5 illustrates a configuration of the base n counter 35 illustrated in FIG. 2.

A counter 60 is a binary counter, and increases sequentially from “0” by receiving inputs of clock signals. When a base n counter is to be configured, a bit number k that can be counted to a value greater than n is prepared for the counter 60 (“2**k>n” has to be satisfied). In a register 61, “n−1” is set. As this value, the value of the error causing interval unit 32 of the control register 30 illustrated in FIG. 2 is set. Specifically, the value is a value obtained by dividing, by the clock cycle, a time interval for writing inverted data to a desired memory. The comparator 62 compares the value increased by the counter 60 and the value of the register 61, and when the compared values match, a clear signal is input to the counter 60.

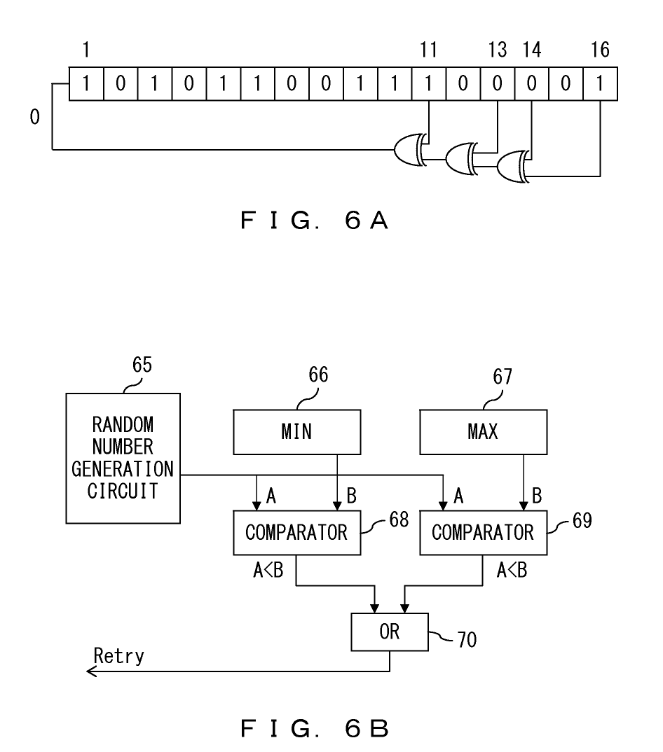

FIGS. 6A and 6B illustrate configurations of the address unit 39 having the minimum and maximum values and the bit selection unit 40 of the random number generator 37 illustrated in FIG. 2.

The address unit 39 and the bit selection unit 40 of the random number generator 37 illustrated in FIG. 2 are configured by random number generation circuits, respectively. The address unit 39 randomly specifies addresses at which simulated errors are to be caused, and the bit selection unit 40 randomly specifies bit positions at which the bits are to be inverted. The minimum and maximum values of addresses and bit positions at which errors are to be caused are specified by the capacity, the bit width, etc., of the target memory. An example will be illustrated below.

FIG. 6A illustrates an example of a random number generation circuit 65. This configuration generates arbitrary random numbers ranging from 1 through 65535. FIG. 6B illustrates a configuration for setting the maximum and minimum numbers as random numbers generated by the random number generation circuit 65. In a minimum value register (MIN) 66, the minimum value that a random number can be is set. In a maximum value register (MAX) 67, the maximum value that a random number can be is set. When a random number is generated by the random number generation circuit 65, a comparator 68 compares the minimum value in the minimum value register (MIN) 66 and the random number. When the random number is smaller, the minimum value register (MIN) 66 outputs “1”. The comparator 69 compares the maximum value in the maximum value register (MAX) 67 and the random number, and when the random number is greater, the maximum value register (MAX) 67 outputs “1”. An OR circuit 70 performs an OR operation between the outputs from the comparators 68 and 69. When the output from the OR circuit 70 is “1”, a retry request is issued to the random number generation circuit 65 in order to make the random number generation circuit 65 generate a new random number. In other words, when a generated random number is smaller than the minimum value or is greater than the maximum value, a random number is generated again. When a random number is to be generated, a random value is generated in a random order, and thus, even when a random number is out of the range between the maximum and minimum values, the random number generated next may be within the range. Until a random number that is within the range between the maximum and minimum numbers is generated, this process is retried. In addition, in this exemplary circuit, “0000000000000000” cannot be generated. However, if a circuit that adds “−1” is added, it becomes possible to generate “0000000000000000”.

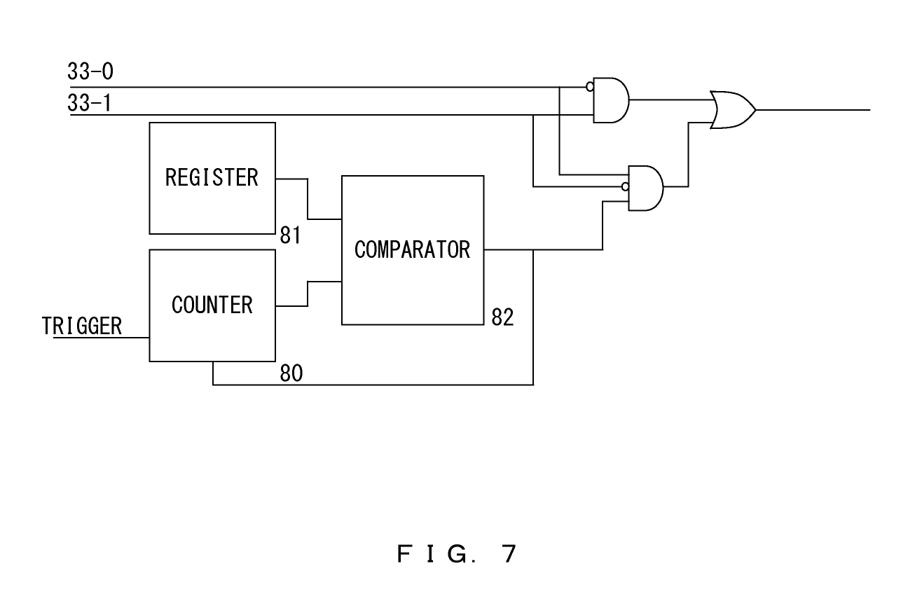

FIG. 7 illustrates a multi-bit error generation ratio control unit 38 in detail. A counter 80 using a trigger signal as a clock, a register 81, and a comparator 82 constitute a base n counter. The value of n specifies the ratio between the number of times that a single-bit data inversion occurs and the number of times that a double-bit data inversion occurs. When the output from the comparator is “1” and the value of the multi-bit error control unit 33 of the control register 30 is “01”, the multi-bit error causing ratio control unit 38 outputs “1” so as to write, to the same address of the memory, data in which two bits have been inverted only once out of n times. When the multi-bit error control unit 33 outputs “00”, the multi-bit error causing ratio control unit 38 always outputs “0”, and two-bit inverted data is not written. When the multi-bit error control unit 33 outputs “10”, the multi-bit error causing ratio control unit 38 always outputs “1”, and data in which two bits have been inverted is written.

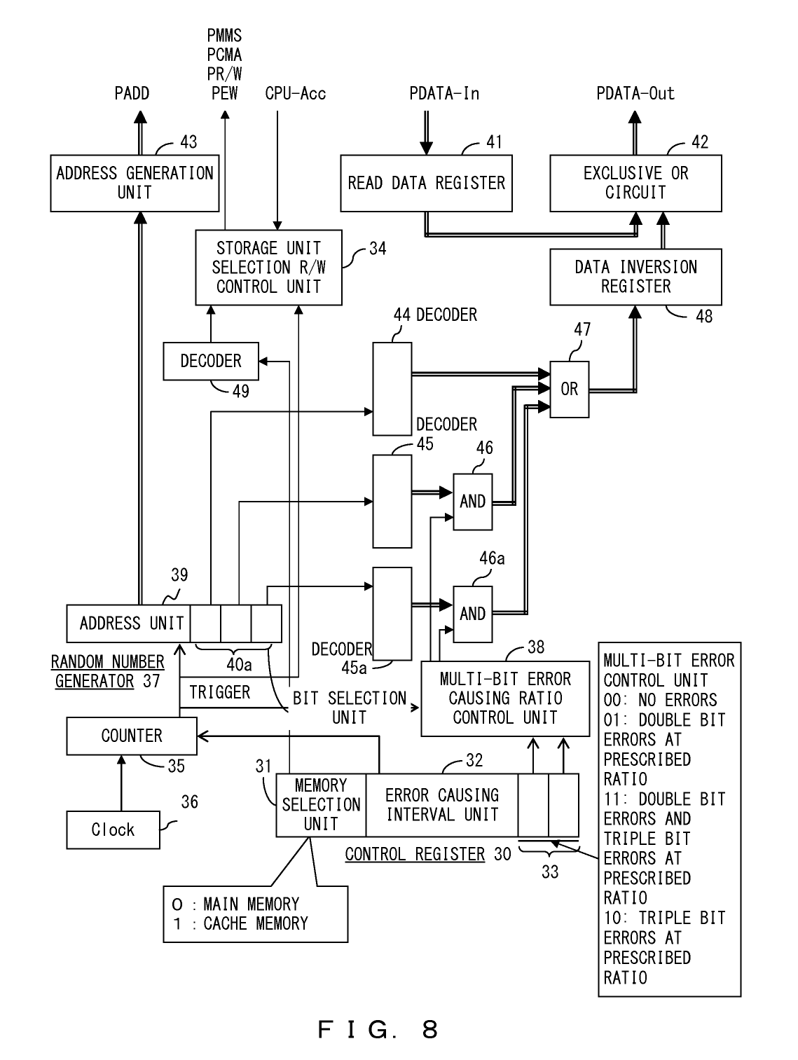

FIG. 8 illustrates a configuration of a simulated error causing unit to cause a triple-bit error as a simulated multi-bit error.

In FIG. 8, the same constituent elements as those in FIG. 2 are denoted by the same symbols, and their explanations are omitted.

In FIG. 8, a bit selection unit 40a generates three bit selection positions, and a decoder 45a and an AND circuit 46a are added newly. In the multi-bit error control unit 33 in the control register 30, settings as below are possible as examples:

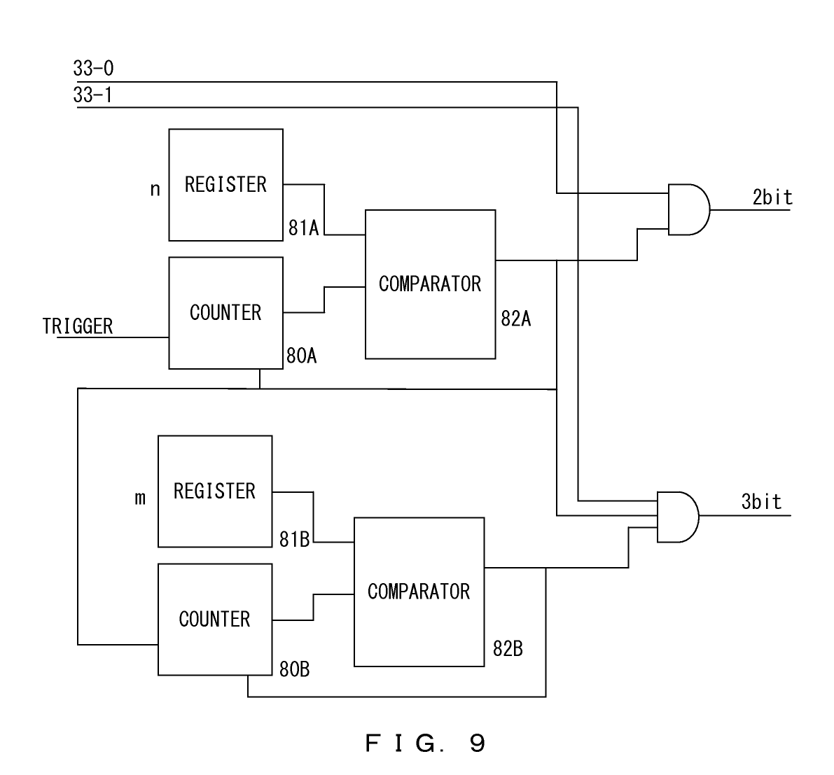

(1) Only a single-bit error occurs, and multi-bit errors do not occur.
(2) A single-bit error occurs, and double-bit errors occur at a prescribed ratio.
(3) Single-bit errors and triple-bit errors occur at a prescribed ratio, and double-bit errors do not occur.
(4) Single-bit errors and double- or triple-bit errors occur independently at prescribed ratios. These “prescribed ratios” are determined by the multi-bit error causing ratio control unit 38. Detailed explanations are given by referring to FIG. 9. In this example, a base n counter is configured by setting the value in the register 81A to “n−1” by using a counter 80A and the comparator 82A. Also, a base m counter is configured by setting the value in the register 81B to “m−1” by using the counter 80B, and the comparator 82B; however, the clock of the counter 80B is supported by outputs from the comparator 82A, and accordingly, the entire counter serves as a base “n+m” counter. When the two bits of the multi-bit error control unit 33 of the control register 30 are “00”, outputs from both counters are closed in the AND circuit, and only single-bit data inversion occurs, without the occurrence of data inversion of double bits or triple bits. When the bits of the multi-bit error control unit 33 are “01”, double-bit inversion data is written once for n times, n being the value set in the register 81A, triple-bit data inversion does not occur, and single-bit inversion occurs “n−1” times for n times. When the bits of the multi-bit error control unit 33 are “10”, triple-bit inversion data is written once for “n×m” times, and single-bit inversion data is written “n×m−1” times for “n×m” times. When the bits of the multi-bit error control unit 33 are “11”, triple-bit inversion data is written once for “n×m” times, double-bit inversion data is written “m−1” times for “n×m” times, and single-bit inversion data is written “n−1” times for “n” times. Thereby, single-bit inversion data, double-bit inversion data, and triple-bit inversion data are written appropriately so that errors are caused at a particular ratio.

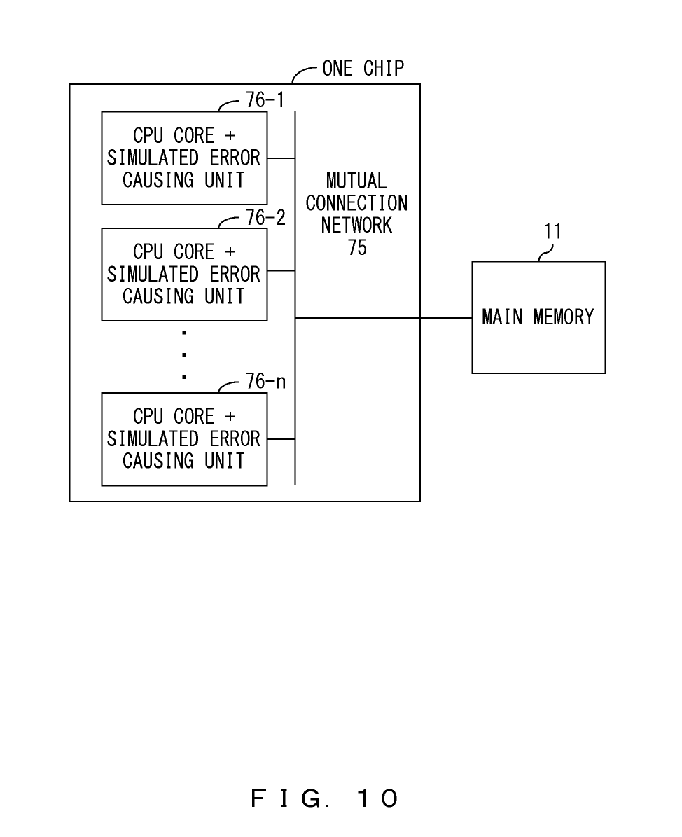

FIG. 10 illustrates a configuration of a first example of a multi-core information processing apparatus, which has a plurality of CPUs, to which the present embodiment is applied.

Each CPU core is provided with cache memory. Also, nodes 76-1 through 76-n each including CPU cores are connected to each other by a mutual connection network 75 in order to access the external main memory 11. The simulated error causing unit according to the present embodiment is provided to each of the nodes 76-1 through 76-n. Each simulated error causing unit not only causes a simulated error in the cache memory of each of the nodes 76-1 through 76-n, but also causes a simulated error in the main memory 11.

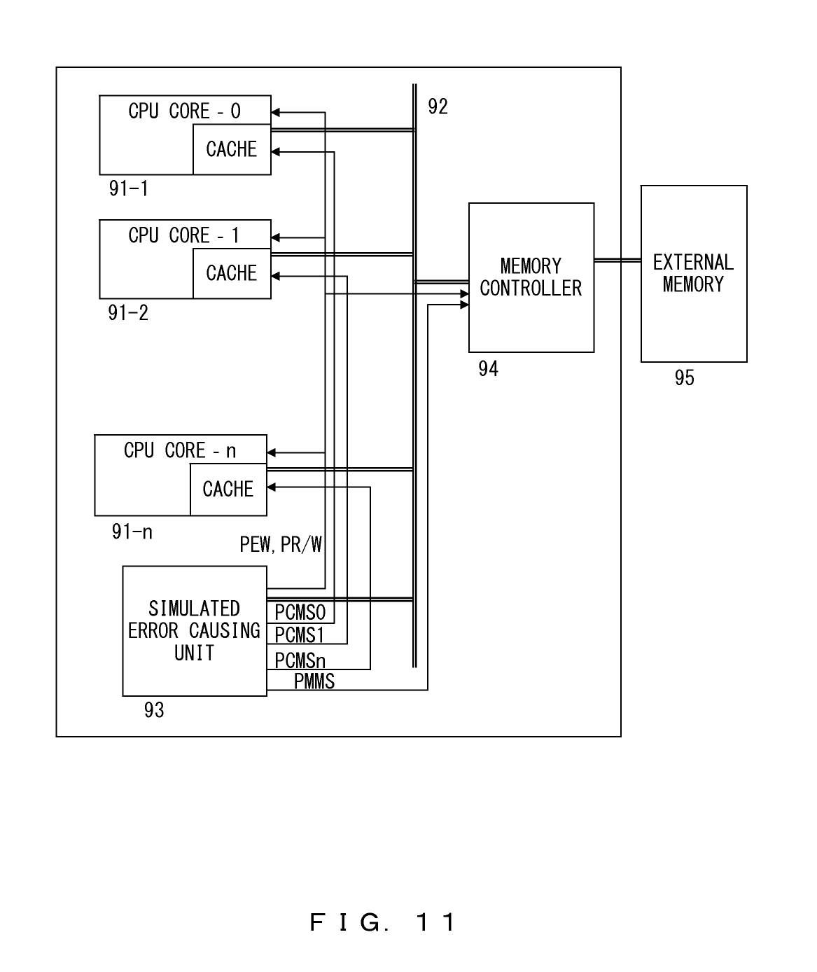

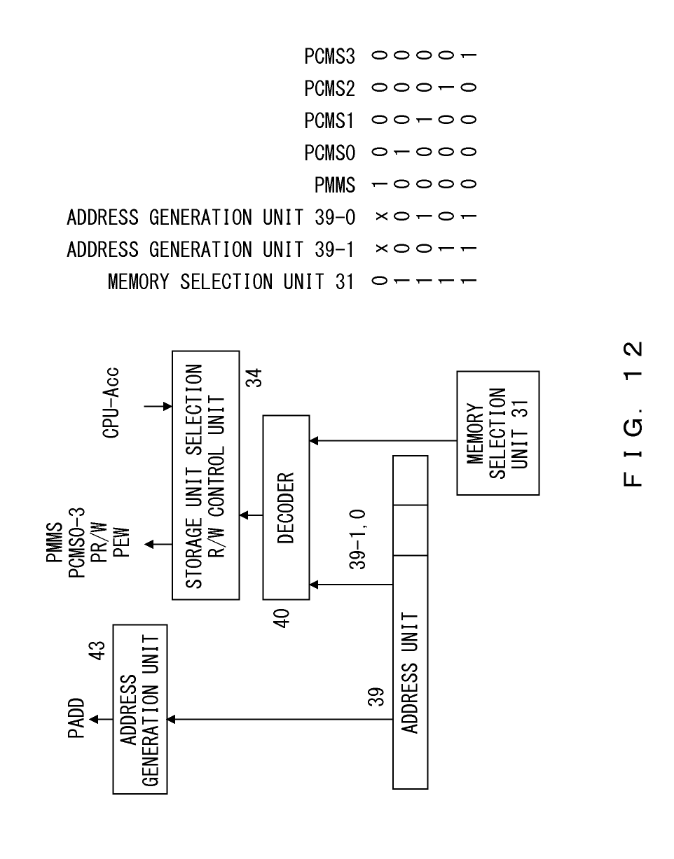

FIG. 11 illustrates a configuration of a second example of a multi-core information processing apparatus, which has a plurality of CPUs, to which the present embodiment is applied. Each CPU core is provided with cache memory. CPU cores 91-1 and 91-2 through 91-n are connected by a general connection network 92. A simulated error causing unit 93 according to the present invention is also connected to the general connection network 92. In this example of the invention, the simulated error causing unit 93 by itself can separately access cache memory devices in the respective CPUs. Specific explanations will be given by referring to FIG. 12. FIG. 12 illustrates a part of FIG. 2 in an enlarged manner, and members not illustrated in FIG. 12 are to be considered the same as those illustrated in FIG. 2. In this example, the address unit 39 illustrated in FIG. 2 is expanded, and part of the address unit 39 is input to the decoder 49, and the input data is decoded as illustrated in the table in FIG. 12 so that the data serves as a selection signal of each cache. Each cache memory selection signal PCMS0 through PCMSn−1 serves as a signal to select the cache memory in each CPU core. Other signals PR/W and PEW are together input to all cache memory devices, and signal PMMS serves as a selection signal for the main memory. Thereby, it is possible to randomly invert data in the cache memory in each CPU core.

In addition, the above present embodiment may be implemented by software. For example, the counters may be implemented in the form of interrupt signals that are issued periodically to determine at what address/bit portions in which of the memory devices simulated errors are to be caused.

Also, a soft error ratio may sometimes vary very greatly depending upon whether memory devices are in an Act Mode for normal reading/writing or in a Dret Mode only for holding data that has been written. In the present embodiment, it is also possible to prepare a plurality of simulated error causing interval registers for the simulated error causing unit in order to reduce the degree of variation of the soft error ratio due to the difference of operation modes so that the simulated error causing intervals can be adjusted in response to the operation modes.

In the explanations of the above embodiments, an example has been used in which the target memory selection unit of the control register is set to either cache memory or main memory so as to perform tests separately when there are both main memory and cache memory. However, in the actual environment, errors occur in both types of memory at random. Thus, it is also possible to prepare a plurality of simulated error causing units according to the present embodiment, setting one for main memory and the other for cache memory to perform tests so that tests can be performed in an environment closer to the actual environment.

Hereinbelow, explanations will be given for how to predict an error occurrence ratio in an actual apparatus.

Usually, DRAM (Dynamic Random Access Memory) is used as the main memory, and this memory is put under an accelerated environment, i.e., a DRAM element itself is forcibly irradiated with alpha rays or neutron rays. It may be assumed that A/B expresses the error occurrence ratio under the actual environment where A represents the error occurrence ratio upon the irradiation (the number of errors occurring in unit time), and B represents the acceleration factor (the ratio between the alpha/neutron ray quantity under normal environments and the ray quantity under the accelerated environment). However, the actual operation conditions of the apparatus are not taken into consideration for the calculation of this value because error occurrence ratio A is measured using a program for testing, and this program for testing writes “1” to all addresses in the memory, and reads “1” from all addresses after a prescribed period of time, and thereafter it writes “0” to all addresses, and reads “0” from all addresses after a prescribed period of time, and this is repeated. By contrast, it is rare to use all addresses effectively, and written data often fails to be read. Accordingly, it is not appropriate to consider A/B as the predicted error ratio.

For cache memory, a memory chip that has been produced by using the same processes as used for the production of cache memory is usually used to predict the error ratio in the same method as the above described method for main memory. However, values obtained by this method are not appropriate for use as values under the actual apparatus environment. For example, operations of data cache memory differ greatly depending upon whether the operation mode is the write back mode or the write through mode. Because in write back operations, an occurrence of a miss hit in cache for data written by the CPU leads to operations of writing back the data to the main memory after an unspecified period of time, when this operation is performed, information is read from the cache memory, and if part of the information written at the address has been inverted, an error occurs. However, in the write through mode, the same information is written to the cache memory and the main memory at the same time, and thus reading of information from cache memory in response to a miss hit in the cache memory is not performed. Thus, even when information of the address in the cache memory has been inverted, no errors occur. In other words, an error ratio for the write through mode is lower.

Taking the above factors into considerations, the error ratio (A/B) of the memory alone is defined as the probability that memory information has been inverted, and a value obtained by multiplying D (1000 through 100,000) by A/B, that is, (D×A/B), is set as an error occurrence time interval of the control register. As the error occurrence intervals of the control register, a period of time ranging roughly from 1 minute through 1 hour is set. From this setting and the value of A/B, the value of D can be roughly determined. Thereafter, a simulated error generation unit according to the present embodiment is used to observe an occurrence of errors after making the actual apparatus environment, the processor operation conditions, and the programs equal to those for the actual operations so as to evaluate whether or not processing routines operate properly for the occurrence of an error. Also, it is possible to predict the error ratio (E) of the actual apparatus by removing this error ratio by dividing the error ratio by value D. When this value (E) is equal to or smaller than a desired error ratio of the apparatus, it is not problematic, however, when the value (E) is equal to or greater than the desired error ratio, countermeasures are required.

In the above embodiment, a main memory that is provided with an ECC has been used as an example of a countermeasure. However, there is also a method in which an ECC is added to a main memory that is not provided with an ECC.

Also, as methods of writing information to cache memory, there are two methods: a write back method and a write through method. Although a write back method has a better performance, a write through method is less vulnerable to soft errors. In a write back method, written information is often written back to the main memory after a long period of time has elapsed, during which inversion of that information occurs, leading to an occurrence of a soft error in the writing back process, whereas in a write through method, written information is immediately written back to the main memory, which reduces operations of reading information after long time intervals. This makes the soft error ratio of a write through method lower. Accordingly, it is effective to adopt, as a method of caching, a write through method so as to increase reliability at a slight caching performance cost.

In the above embodiments, by producing a phenomenon equivalent to a soft error caused by alpha rays or cosmic rays (neutron rays) so as to cause a soft error phenomenon in an accelerated state, which can occur in rare cases, it is possible to confirm whether or not a routine for processing soft errors is operating properly as an apparatus. Also, because the error occurrence ratio of the apparatus may be predicted, it is possible to confirm whether or not countermeasures are necessary.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an indication of superior and inferior aspects of the invention. Although the embodiments of the present invention have been described in detail, it should be understood that various changes, substitutions, and alterations could be made hereto without departing from the spirit and scope of the invention.

What is claimed is:

1. A simulated error causing apparatus, comprising:
an information storage unit to store data including an information bit and a redundant bit;
a reading unit to read, from an arbitrarily set address in the information storage unit, data including the information bit and the redundant bit without performing error detection or error correction; and
a writing back unit to invert at least one bit at an arbitrarily set bit position in the read data including the information bit and the redundant bit, and to write back the bit-inverted data to an original address in the information storage unit.

2. The simulated error causing apparatus according to claim 1, further comprising:
an error causing interval setting unit to set a time interval at which a series of operations including a reading operation by the reading unit and a writing back operation by the writing back unit is repeatedly performed.

3. The simulated error causing apparatus according to claim 2, wherein:
the error causing interval setting unit includes a plurality of setting units holding different time intervals, and is capable of using the setting units while switching from one of the setting units to another.

4. The simulated error causing apparatus according to claim 1, wherein:
the information storage unit includes a plurality of memory devices; and
the apparatus further comprises a memory selection unit that is capable of setting which of the memory devices a reading operation by the reading unit and a writing back operation by the writing back unit are to be performed on.

5. The simulated error causing apparatus according to claim 1, wherein
a reading operation by the reading unit and a writing back operation by the writing back unit are performed after a CPU terminates access to the information storage unit.

6. The simulated error causing apparatus according to claim 1, wherein:
access by a CPU to the information storage unit is not allowed while a reading operation by the reading unit and a writing back operation by the writing back unit are performed.

7. The simulated error causing apparatus according to claim 1, wherein:
the arbitrarily set address is specified by a random number generated within a range defined by a maximum value and a minimum value.

8. The simulated error causing apparatus according to claim 1, wherein:
the arbitrarily set bit position is specified by a random number generated within a range defined by a maximum value and a minimum value.

9. The simulated error causing apparatus according to claim 1, wherein:
the information storage unit is cache memory; and
a reading operation by the reading unit and a writing back operation by the writing back unit are performed for data including an information bit containing the tag portion stored in the cache memory and a redundant bit.

10. The simulated error causing apparatus according to claim 1, further comprising:
a base n counter that is capable of setting n as a value increased by the base n counter, where n is a maximum value, wherein:
a simulated error of two or more bits is caused once while a simulated error of one bit is caused n times.

11. The simulated error causing apparatus according to claim 1, wherein
the reading unit and the writing back unit are provided in a plurality of sets, respectively.

12. The simulated error causing apparatus according to claim 1, provided with
a plurality of CPUs having cache memory devices; and
a mechanism to allocate addresses to the plurality of cache memory devices in the plurality of CPUs, and to generate the addresses randomly.

13. A semiconductor device, comprising:
the simulated error causing apparatus according to claim 1.

14. A method of causing a simulated error in an information apparatus having an information storage unit to store data including an information bit and a redundant bit, comprising:
reading, from an arbitrarily set address in the information storage unit, data including the information bit and the redundant bit without performing error detection or error correction; and
inverting at least one bit at an arbitrarily set bit position in the read data including the information bit and the redundant bit, and writing back the bit-inverted data to an original address in the information storage unit.
